(19) United States
(12) Patent Application Publication
(10) Pub. No.: US 2018/0372672 A1
(43) Pub. Date: Dec. 27, 2018

(54) ELECTROCHEMISTRY DEVICE WITH IMPROVED ELECTRODE ARRANGEMENT

(71) Applicant: PROTOCHIPS, INC., Morrisville, NC (US)

(72) Inventors: Franklin Stampley Walden, II, Morrisville, NC (US); Ian Patrick Wellenius, Morrisville, NC (US); John Damiano, JR., Morrisville, NC (US); David P. Nackashi, Morrisville, NC (US); Daniel Stephen Gardiner, Morrisville, NC (US)

(21) Appl. No.: 16/013,990

(22) Filed: Jun. 21, 2018

Related U.S. Application Data
(60) Provisional application No. 62/523,037, filed on Jun. 21, 2017.

(51) Int. Cl. G01N 27/403

(52) U.S. Cl. CPC G01N 27/403; H01J 37/26

(57) ABSTRACT

An electrochemistry device for electrically measuring a sample during electron microscope imaging includes: a planar chip having a first longitudinal end along which at least three laterally spaced contact electrodes are positioned; a laterally extending working electrode in electrical communication with a first of the three contact electrodes; a counter electrode spaced from and at least partially encircling the working electrode, the counter electrode in electrical communication with a second of the three contact electrodes; and a reference electrode in electrical communication with a third of the three contact electrodes, the reference electrode positioned outside of an area defined between the working electrode and counter electrode.

### CROSS-REFERENCE TO RELATED APPLICATIONS

This application claims priority to U.S. Provisional Patent Application No. 62/523,037 filed on Jun. 21, 2017, and entitled Electrochemistry Device With Improved Electrode Arrangement. The contents are incorporated by reference herein.

### TECHNICAL FIELD

The present disclosure relates to sample support devices for use in electron microscopy. More particularly, the present disclosure relates to a device enabling electrochemical reactions and electron microscopy viewing while optimizing X-ray analysis.

### BACKGROUND

A prior art electrochemistry device includes a working electrode on a thin window. A counter electrode partially surrounds the window and the working electrode. In use, the working electrode and counter electrode are wetted in a liquid environment in which an electrochemistry reaction occurs for observation as a signal is sourced between the working electrode and counter electrode. The working electrode is positioned on the window so a user can see the reaction at the working electrode. However, due to the arrangement of the working electrode, line of sight from the working electrode and window to nearby detectors can be obstructed by frame portions of the chip, reducing detection efficiency.

Furthermore, a reference electrode positioned between the working and counter electrodes in the prior art electrochemistry device can become dewetted and thus destabilize the measurement arrangement.

### SUMMARY

This summary is provided to introduce in a simplified form concepts that are further described in the following detailed descriptions. This summary is not intended to identify key features or essential features of the claimed subject matter, nor is it to be construed as limiting the scope of the claimed subject matter.

In at least one embodiment, an electrochemistry device for electrically measuring a sample during electron microscope imaging includes: a planar chip having a first longitudinal end along which at least three laterally spaced contact electrodes are positioned; a laterally extending working electrode in electrical communication with a first of the three contact electrodes; a counter electrode spaced from and at least partially encircling the working electrode, the counter electrode in electrical communication with a second of the three contact electrodes; and a reference electrode in electrical communication with a third of the three contact electrodes, the reference electrode positioned outside of an area defined between the working electrode and counter electrode. While this describes a particular example, an electrochemical cell without a counter electrode encircling the working electrode is within the scope of these descriptions. Such a counter electrode for example could be larger than the working electrode and peripherally arranged or spaced further from the counter electrode. Thus examples here are not to be taken as limiting.

In at least one example, no portion of the reference electrode is positioned between any portion of the working electrode and any portion of the counter electrode. While this describes a particular example, an electrochemical cell could be made with the reference electrode between the working electrode and counter electrode. The reference electrode could be spaced far enough away from the working electrode and counter electrode and large enough to increase probability of staying wet. Thus examples here are not to be taken as limiting.

In at least one example, the working electrode is an elongate linear electrical conducting member having a laterally extending length that is greater than its width.

In at least one example, the working electrode is positioned on an electron-transparent window.

In at least one example, the electron-transparent window is aligned with a beveled aperture formed in the planar chip.

In at least one example, the electron-transparent window extends laterally with respect to the holder.

### BRIEF DESCRIPTION OF THE DRAWINGS

The previous summary and the following detailed descriptions are to be read in view of the drawings, which illustrate particular exemplary embodiments and features as briefly described below. The summary and detailed descriptions, however, are not limited to only those embodiments and features explicitly illustrated.

FIG. 1 is a perspective view of an electrochemistry device, according to the prior art, for mounting in the tip of a sample holder for electron microscope imaging.

FIG. 2 is a plan view of a central portion of the electrochemistry device of FIG. 1.

FIG. 3 is a plan view of an improved electrochemistry device, according to at least one embodiment, for mounting in the tip of a sample holder for electron microscope imaging, showing the interior side for facing into an electrochemistry cell.

FIG. 4 shows the exterior or vacuum side of the electrochemistry device of FIG. 3.

FIG. 5 shows the interior-side layers of the electrochemistry device of FIG. 3, from the perspective of FIG. 4, with the chip removed from view.

FIG. 6 shows a partial cross section of the electrochemistry device of FIG. 3, showing the working electrode on the silicon window layer.

FIG. 7 shows the chip of the electrochemistry device of FIG. 3 in perspective view, cross-sectioned along a slot and showing a beveled aperture.

FIG. 8 is an enlarged view of a central portion of electrochemistry device of FIG. 3, as marked by dashed line in FIG. 5.

FIG. 9 is a longitudinal view of a cross sectioned sample holder holding the electrochemistry device of FIG. 3 in an electron microscope.

### DETAILED DESCRIPTIONS

These descriptions are presented with sufficient details to provide an understanding of one or more particular embodiments of broader inventive subject matters. These descriptions expound upon and exemplify particular features of those particular embodiments without limiting the inventive subject matters to the explicitly described embodiments and features. Considerations in view of these descriptions will likely give rise to additional and similar embodiments and features without departing from the scope of the inventive subject matters. Although steps may be expressed or implied relating to features of processes or methods, no implication is made of any particular order or sequence among such expressed or implied steps unless an order or sequence is explicitly stated.

Any dimensions expressed or implied in the drawings and these descriptions are provided for exemplary purposes. Thus, not all embodiments within the scope of the drawings and these descriptions are made according to such exemplary dimensions. The drawings are not made necessarily to scale. Thus, not all embodiments within the scope of the drawings and these descriptions are made according to the apparent scale of the drawings with regard to relative dimensions in the drawings. However, for each drawing, at least one embodiment is made according to the apparent relative scale of the drawing.

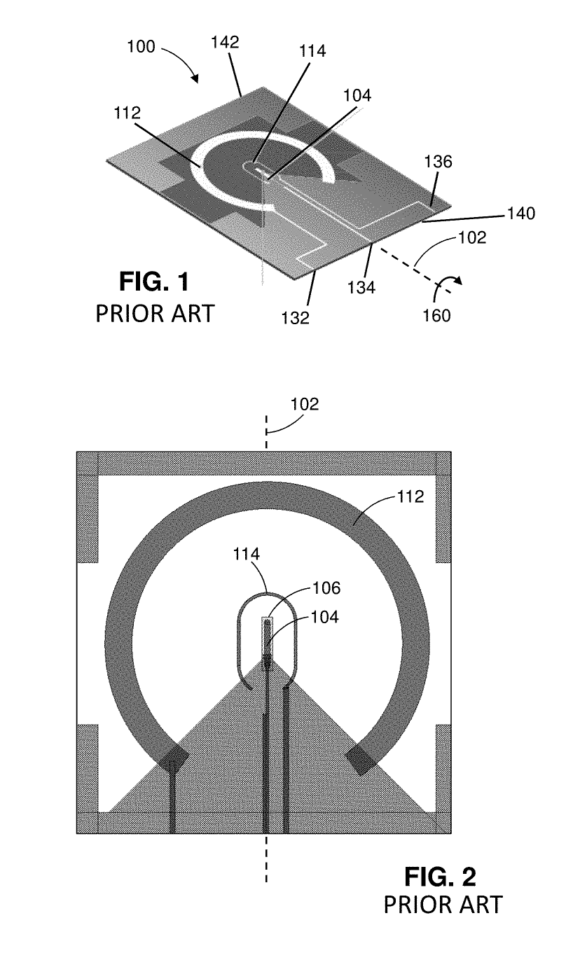

An electrochemistry device 100, representative of the prior art, for use in electrically stimulating and characterizing a sample is shown in FIGS. 1 and 2. In use, the electrochemistry device 100 would be mounted in the tip of a sample holder for placement of a sample in the beam of an electron microscope for imaging. A typical sample holder can be rotated around a central longitudinal axis 102 so as to orient the electrochemistry device 100 in a preferential direction with respect to nearby detector systems.

The electrochemistry device 100 includes a working electrode 104 on a thin window 106. A counter electrode 112 partially surrounds the window 106 and working electrode 104. In use, the working electrode 104 and counter electrode 112 are wetted in a liquid environment in which an electrochemistry reaction occurs for observation as a signal is sourced between the working electrode 104 and counter electrode 112. The working electrode 104 is positioned on the window 106 so a user can see the reaction at the working electrode 104. The working electrode 104 is typically imaged during the reaction. A signal between the working electrode 104 and a reference electrode 114 is measured to isolate electrical behavior of the working electrode 104.

Electrically conducting leads extend respectively from the counter electrode 112, working electrode 104, and reference electrode 114 to terminal ends 132, 134 and 136, which are laterally spaced along a longitudinal end 140 of the electrochemistry device 100 for electrical contact with corresponding contacts of a sample holder when the electrochemistry device 100 is mounted for use.

In a typical mounting arrangement in a sample holder, the proximal longitudinal end 140 (FIG. 1) is directed toward a barrel by which the sample holder is supported in use in an electron microscope. An opposite distal longitudinal end 142 of the electrochemistry device 100 is directed away from the barrel and toward the free end of the tip of the sample holder.

In FIGS. 1 and 2 the counter electrode 112 partially surrounds the window 106 and working electrode 104. The reference electrode 114 partially surrounds the window 106 and working electrode 104. The reference electrode 114 is positioned between the working electrode 104 and counter electrode 112, for example blocking line of sight between any portion of the counter electrode 112 and any portion of the working electrode 104. In use, the working electrode 104 and counter electrode 112 are wetted in a liquid environment in which an electrochemistry reaction occurs for observation as a signal is sourced between the working electrode 104 and counter electrode 112, as the working electrode is imaged.

When the electrochemistry device 100 is mounted in the tip of a sample holder and used in electron microscopy, an electron beam strikes the sample and X-rays are emitted in all directions. The X-rays are typically detected by energy-dispersive (EDS) detectors. The detector signals are analyzed to map peaks in the emitted X-ray spectrum and permit elemental analysis of the sample under observation. Such EDS detectors are typically mounted in a right-angle arrangement relative to the central longitudinal axis 102 and above the plane of the electrochemistry device. The sample holder is typically rotated around the central longitudinal axis 102 by rotation of the barrel in its mount in the electron microscope housing, as represented by the turn 160 in FIG. 1.

In the illustrated prior art electrochemistry device 100, the working electrode 104 extends parallel to the longitudinal axis 102 and thus line of sight between the working electrode and EDS detectors is not optimized by this arrangement. X-ray detection is limited in most closed-cell constructions, in which the subject of electron microscopy is isolated or separated from the vacuum column of the microscope. Such isolation is of course needed for example whenever a subject is maintained in aqueous or other liquid environment or is under gas pressure, however rarefied, during observation. Isolation is typically achieved by some sort of cell arrangement, closed to the vacuum, with thin membranes and supporting framing structures that ultimately can limit X-ray detection efficiency. Furthermore, as an electrochemistry reaction occurs, gas can be produced or released, particularly at the working electrode 104 such that bubbles can accumulate. The reference electrode 114 can become dewetted, a condition which destabilizes good measurement and characterization.

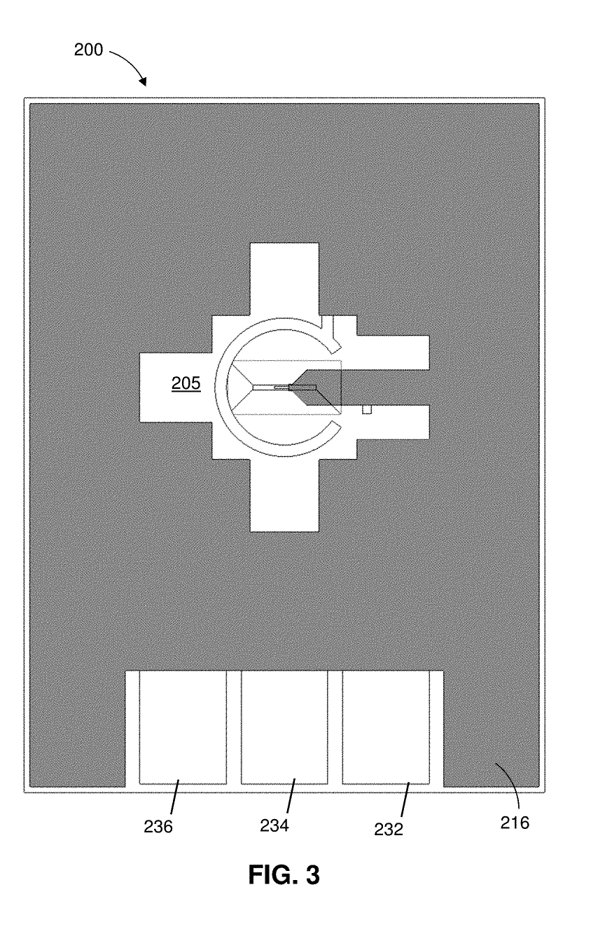

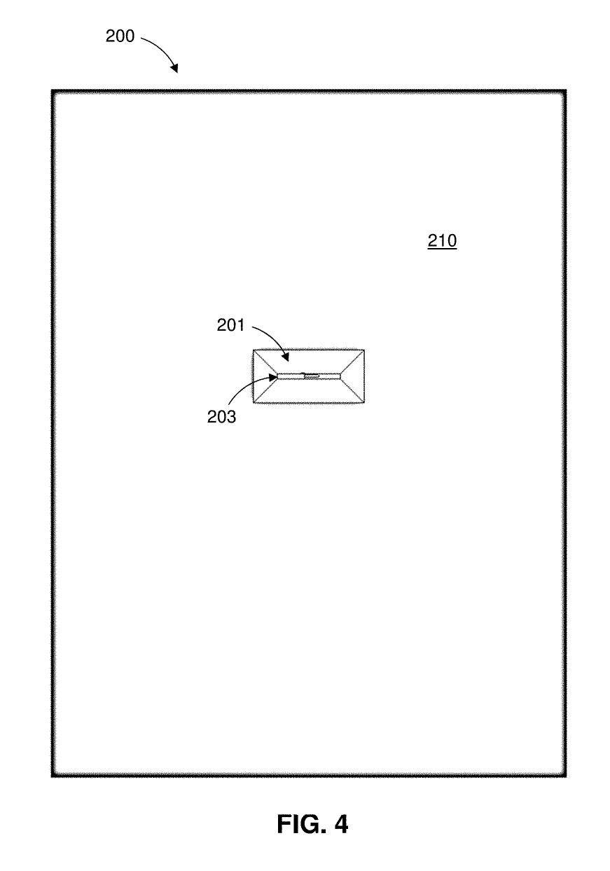

An improved electrochemistry device 200, having advantageous electrode placements and geometries, is shown in FIGS. 3-8. In FIG. 3, the interior side of the electrochemistry device 200 is shown. In FIG. 4, the exterior or vacuum side of the electrochemistry device 200 is shown. Interior and exterior refer to an electrochemistry cell of which the electrochemistry device 200 typically forms a top part when the cell is in use in an electron microscope such that the interior side (FIG. 3) faces downward into the cell and the exterior side (FIG. 4) faces upward toward an incident electron beam.

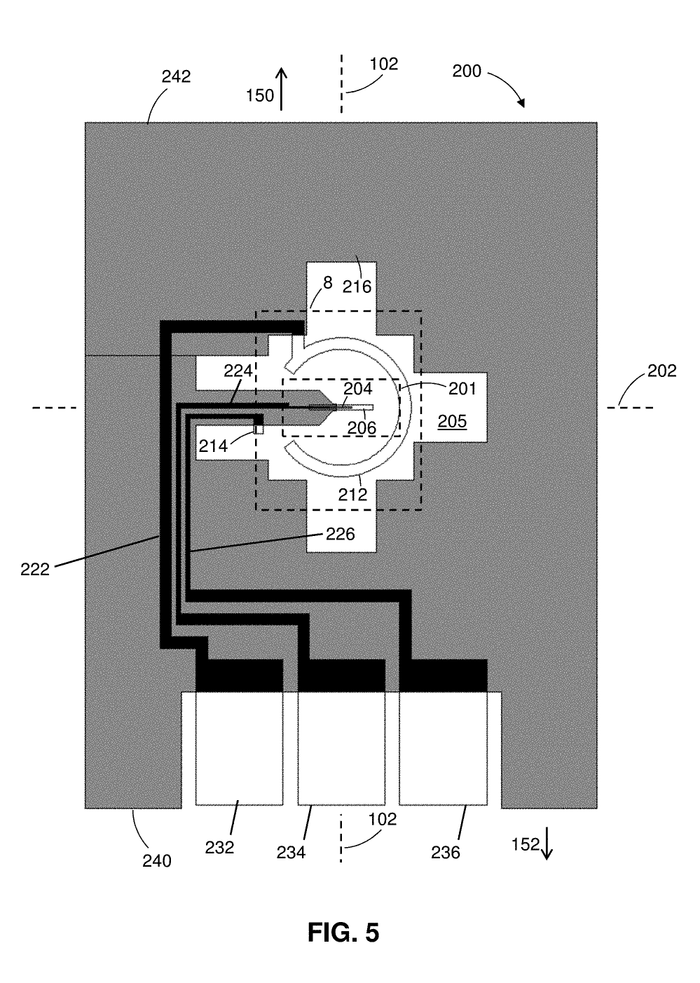

As shown in FIG. 4, the electrochemistry device 200 includes a chip 210 in which an aperture 201 is formed. The aperture 201 is beveled from the exterior side to the interior side, narrowing to a slot 203. The substrate is typically silicon, which when etched along the 1,1,1 plane leaves behind a bevel. FIG. 5 shows the interior side layers of the electrochemistry device 200 in the disposition of FIG. 4 with the chip 210 removed from view. The outline of the aperture 201 at the exterior surface of the chip is shown in broken line for reference.

A window layer 205 (FIG. 5) generally across the chip 210 seals the electrochemistry device 200 from the interior side. The window layer 205 may be constructed of SiN for example. At the slot 203 (FIG. 4), a window 206 (FIG. 5) is formed by the window layer 205, which may be constructed of SiN for example, through which an electron beam will enter from the exterior side in use. Other example materials by which the window layer may be constructed include Boron Nitride, Diamond, doped diamond, or any other thin film.

A working electrode 204 (FIG. 5) is placed on the interior side of the window layer 205 at the window 206. A counter electrode 212 on the window layer 205 partially surrounds the window 206 and working electrode 204. In use, the working electrode 204 and counter electrode 212 are wetted in a liquid environment in which an electrochemistry reaction occurs for observation as a signal is sourced between the working electrode 204 and counter electrode 212.

The working electrode 204 is positioned on the window layer 205 at the window 206 so a user can see the reaction at the working electrode 204. The working electrode 204 is typically imaged by electron microscopy during the reaction. A signal between the working electrode 204 and reference electrode 214 is measured to isolate electrical behavior of the working electrode 204. The assignment of the electrodes 204, 212 and 214 as the working, counter, and reference electrode respectively is not the only possible or useful way to utilize the electrodes. For example, a user can plate the electrode 204 by assigning it as the counter electrode. The reference electrode can be paired to either the working electrode or the counter electrode in order to make measurements regarding either. Nonetheless, for descriptive convention, the electrodes 204, 212 and 214 are indicated herein as the working, counter, and reference electrode respectively. Furthermore, the electrodes 212 and 214 can be displaced to a small reservoir outside of the chip 210. Thus, there are various arrangements within the scope of these descriptions.

Electrically conducting leads 222, 224 and 226 extend along the window layer 205 from the counter electrode 212, working electrode 204, and reference electrode 214, respectively. The leads 222, 224 and 226 extend to respective electrical contact pads 232, 234 and 236, which are laterally spaced along a longitudinal end 240 of the electrochemistry device 200 for electrical contact with corresponding contacts of a sample holder when the electrochemistry device 200 is mounted for use. Each of the electrical leads 222-226 serves as a separate signal carrying path.

In a typical mounting arrangement, the electrochemistry device 200, which is generally planar, is mounted in the tip of a sample holder with the longitudinal end 240 of the electrochemistry device 200 directed toward a barrel by which the sample holder is supported in use in an electron microscope. An opposite longitudinal end 242 of the electrochemistry device 200 is directed away from the barrel and toward the free end of the tip of the sample holder. Accordingly, for descriptive purposes, the longitudinal end 240, which is typically nearest the barrel when mounted, is described herein as the proximal longitudinal end 240 of the electrochemistry device 200, and the opposite longitudinal end 242 is described as the distal longitudinal end 242.

Thus, the electrochemistry device 200 extends along the longitudinal axis 102 in a first longitudinal direction 150 from its proximal longitudinal end 240 to the distal longitudinal end 242; and the proximal longitudinal end 240 is directed toward a second longitudinal direction 152 opposite the first longitudinal direction 150.

A patterned insulator layer 216 (FIG. 5) insulates the leads 222, 224 and 226 from direct contact with the wet cell environment when the electrochemistry device 200 is in use, while permitting wetting of the working electrode 204, counter electrode 212, and reference electrode 214. The reason existing prior art cells have chips aligned with the axis of the holder, may be because of the small diameter associated with standard TEM holders. This pushes users to align electrical contacts, chips, plumbing lines, etc. axially with the holder in prior art cells.

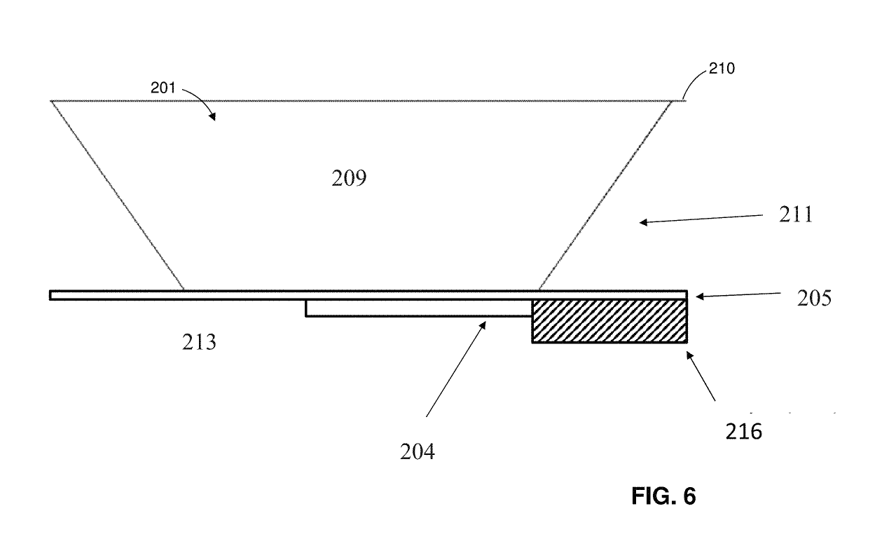

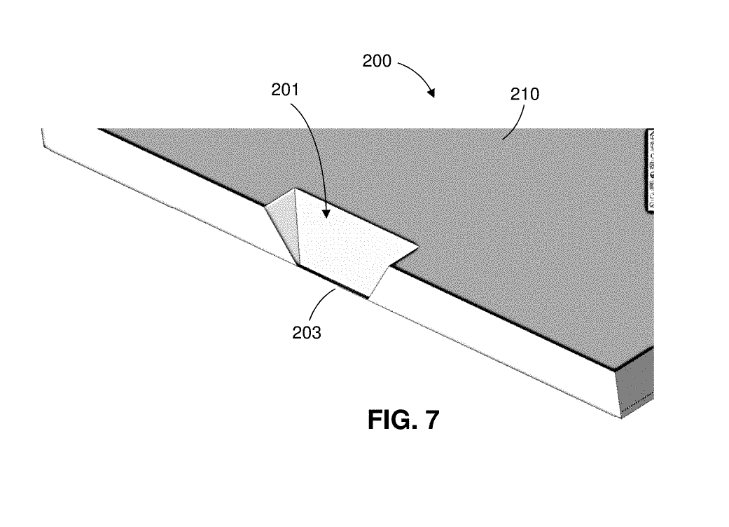

FIG. 6 shows a partial cross section of the electrochemistry device 200 showing the working electrode 204 on the silicon window layer 205. FIG. 7 shows the chip 210 in perspective view, cross-sectioned along the slot 203 and showing the beveled aperture 201. A silicon frame 211 is provided around the beveled aperture 201. An etched silicon over window (vacuum) 209 is provided. A wetted area 213 is defined.

In the electrochemistry device 200 as shown in FIG. 5, the reference electrode 214 is advantageously displaced from between the counter electrode 212 and working electrode 204, with no portion of the reference electrode 214 being positioned between any portion of the working electrode 204 and any portion of the counter electrode 212. Thus the reference electrode is positioned outside of an area defined between the working electrode and counter electrode. This advantageous arrangement, which is distinct from that of the electrochemistry device 100 of the prior art, increases electrical stability by minimizing any likelihood of the reference electrode 214 becoming dewetted by generated or released gases as electrochemistry reactions are prompted by an electrical signal sourced between the working electrode 204 and counter electrode 212. Typical produced or released gases include hydrogen and oxygen in aqueous solutions.

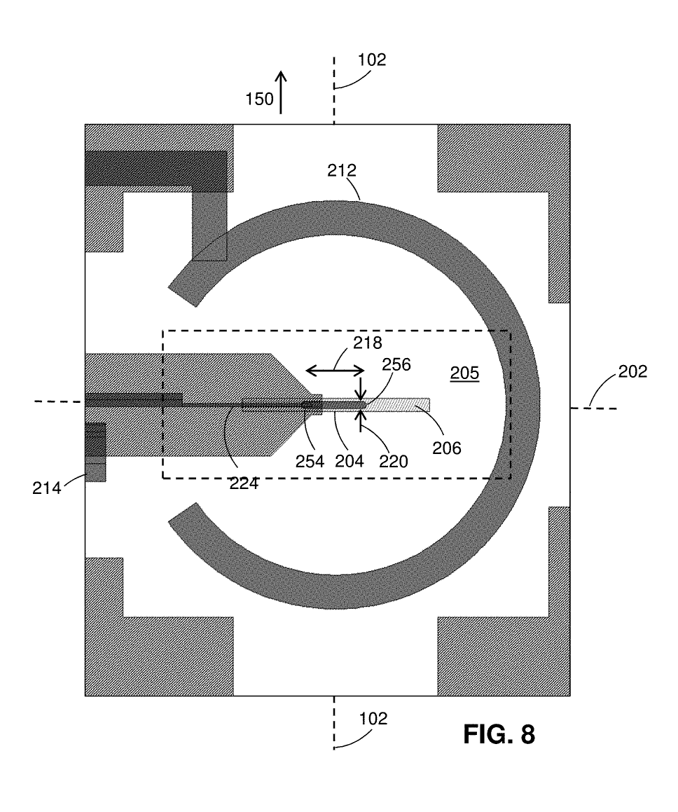

FIG. 8 is an enlarged view of a central portion 8 of electrochemistry device 200 as marked by dashed line in FIG. 5. In the illustrated electrochemistry device 200 (FIG. 5), the working electrode 204 is shown as an elongate linear electrical conducting strand having a length 218 (FIG. 8) that is greater than its width 220. The working electrode 204 extends the length 218 parallel to the lateral axis 202 to a distal end 256. The lateral axis 202 is defined as perpendicular to the longitudinal axis 102. The proximal end 254 (FIG. 8) of the working electrode 204 is directly electrically connected to the lead 224, and thus is in electrical communication with the contact pad 234 (FIG. 5) for electrical communication with a corresponding contact of a sample holder when the electrochemistry device 200 is mounted for use. The distal end 256 can be described as a free terminal end of the working electrode 204. The distal end 256 of the working electrode 204 is electrically connected to the lead 224 by way of the proximal end 254 of the working electrode 204, and thus is in electrical communication with the contact pad 234 only by way of the proximal end 254.

The laterally extending window 206 is long, by length 218 parallel to the lateral axis 202, to increase imageable area. The window is narrow, by width 220 parallel to the longitudinal axis 102 and less than the length, to reduce window bowing (liquid thickness).

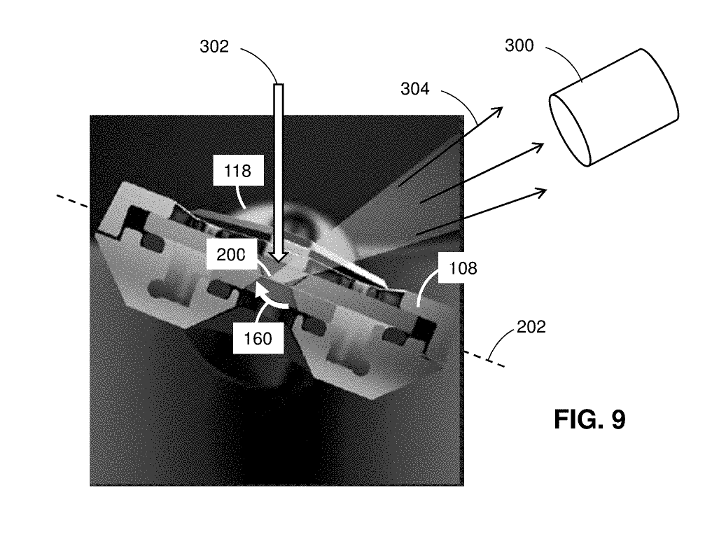

Line of sight from the working electrode 204 (FIGS. 5 and 8) and window 206 to a right-angle detector 300 (FIG. 9) can be improved from a position in which an incident electron beam 302 is normal to the generally planar electrochemistry device 200 by rotation of the electrochemistry device 200 around the longitudinal axis to face the detector. The rotation enhances the detection of X-rays 304 produced at the sample.

In FIG. 9, an electrochemistry cell is formed when a second chip having a thin window and surrounding thicker frame is brought into facing arrangement with the electrochemistry device 200, with the working, counter, and reference electrodes sandwiched between the windows of the two chips in a wet cell electrochemistry environment.

In the illustrated example of FIG. 9, the sample holder is rotated approximately forty-five degrees from facing the electron beam and toward the detector 300 as represented by the turn 160. The rotation by is accomplished by rotation of the sample holder 108 after the electrochemistry device 200 is mounted, and the barrel 118 is mounted in the electron microscope housing. The rotation reduces blocking between the working electrode 204 (FIGS. 5 and 8) and detector 300 (FIG. 9) by the higher portions of the chip body 210 (FIG. 7).

In the illustrated electrochemistry device 200, the working electrode 204 extends the length 218 (FIG. 8) thereof perpendicular to the central longitudinal axis 102, whereas the working electrode 104 in FIGS. 1-2 extends the length thereof parallel to the central longitudinal axis 102. Each working electrode is closely approached by the walls of its correspondingly shaped slot. Thus the arrangement in FIGS. 3-8 is advantageous for line-of-sight optimization when using EDS detectors in electron microscopy while maintaining the relative geometry of the working electrode 204 and counter electrode 212 in their plane in the electrochemistry device 200.

Regarding the electrochemistry device 200 and its components, a closed cell may be 500 nm thick in some examples so that users can image through the liquid layer. Materials for use in constructing the working electrode include, but are not limited to: glassy carbon, and platinum. Materials for use in constructing the reference electrode include, but are not limited to: Ag/AgCl, and platinum. A material for use in constructing the counter electrode includes, but is not limited to, platinum. Platinum is an option for all three electrode materials because it is a well characterized metal and often is utilized when users weld different electrode metals onto the patterned electrodes in a FIB tool. Because users are likely to weld with Pt, this metal can be used as the substrate and no new metals introduced by the welding.

Glassy carbon is an option for the working electrode because an electron transparent electrode that users can see through can be fabricated. Ag/AgCl is an option for reference electrodes because it is stable and characterized, and useful in aqueous solutions.

Particular embodiments and features have been described with reference to the drawings. It is to be understood that these descriptions are not limited to any single embodiment or any particular set of features, and that similar embodiments and features may arise or modifications and additions may be made without departing from the scope of these descriptions and the spirit of the appended claims.

What is claimed is:

1. An electrochemistry device for electrically measuring a sample during electron microscope imaging, the electrical device comprising:
a planar chip having a first longitudinal end along which at least three laterally spaced contact electrodes are positioned;
a laterally extending working electrode in electrical communication with a first of the three contact electrodes;
a counter electrode spaced from and at least partially encircling the working electrode, the counter electrode in electrical communication with a second of the three contact electrodes; and
a reference electrode in electrical communication with a third of the three contact electrodes, the reference electrode positioned outside of an area defined between the working electrode and counter electrode.

2. The electrochemistry device of claim 1, wherein no portion of the reference electrode is positioned between any portion of the working electrode and any portion of the counter electrode.

3. The electrochemistry device of claim 1, wherein the working electrode is an elongate linear electrically conducting member having a laterally extending length that is greater than its width.

4. The electrochemistry device of claim 1, wherein the working electrode is positioned on an electron-transparent window.

5. The electrochemistry device of claim 4, wherein the electron-transparent window is aligned with a beveled aperture formed in the planar chip.

6. The electrochemistry device of claim 4, wherein the electron-transparent window extends laterally.

7. The electrochemistry device of claim 6, wherein the window is longer in a lateral direction than a longitudinal direction that is perpendicular to the lateral direction.

8. The electrochemistry device of claim 1, further including a patterned insulator layer that insulates leads connecting each of the three contact electrons from a respective electrode from a wet cell environment on the electrochemistry device.

9. The electrochemistry device of claim 1, wherein the device is rotated around a longitudinal axis during imaging.
